(19) United States
(12) Patent Application Publication
(10) Pub. No.: US 2014/0225218 A1
(43) Pub. Date: Aug. 14, 2014

(54) ION REDUCED, ION CUT-FORMED THREE-DIMENSIONAL (3D) INTEGRATED CIRCUITS (IC) (3DICS), AND RELATED METHODS AND SYSTEMS

(71) Applicant: QUALCOMM INCORPORATED, San Diego, CA (US)

(72) Inventor: Yang Du, Carlsbad, CA (US)

(73) Assignee: QUALCOMM Incorporated, San Diego, CA (US)

(21) Appl. No.: 13/765,080

(22) Filed: Feb. 12, 2013

(51) Int. Cl. H01L 21/822; H01L 25/065

(52) U.S. Cl. CPC H01L 21/8221; H01L 25/0657
USPC 257/499; 438/458

(57) ABSTRACT

Ion-reduced, ion cut-formed three-dimensional (3D) integrated circuits (IC) (3DICs) are disclosed. Related methods and systems are also disclosed. During an ion-cut process for forming a monolithic 3DIC, extra ions are implanted in the donor wafer to effectuate the ion-cut. Excess, residual implanted ions remain implanted in a top layer of the transfer layer of the 3DIC. However, these residual implanted ions can interfere with operation of electronic components in the 3DIC. In this regard, the 3DIC and methods disclosed herein involve reduction or removal of the residual extra ions before further electronic components are created and layered in a 3DIC. In this manner, the extra charge elements introduced by such extra ions are reduced or removed providing for better functionality in the completed device.

### RELATED APPLICATION

The present application is related to U.S. patent application Ser. No. 13/765,061, filed on Feb. 12, 2013, entitled “THREE DIMENSIONAL (3D) INTEGRATED CIRCUITS (3DICs) WITH GRAPHENE SHIELD, AND RELATED COMPONENTS AND METHODS,” which is incorporated herein by reference in its entirety.

### BACKGROUND

I. Field of the Disclosure

The technology of the disclosure relates to three-dimensional (3D) integrated circuits (IC) (3DICs), and methods of forming same.

II. Background

Mobile communication devices have become common in current society. The prevalence of these mobile devices is driven in part by the many functions that are now enabled on such devices. Demand for such functions increases processing capability requirements and generates a need for more powerful batteries. Within the limited space of the housing of the mobile communication device, batteries compete with the processing circuitry. These and other factors contribute to a continued miniaturization of components and power consumption within the circuitry.

Miniaturization of the components impacts all aspects of the processing circuitry including the transistors and other reactive elements in the processing circuitry. One miniaturization technique involves arranging integrated circuits in not just an x-y coordinate system, but also in a z-coordinate system. That is, current miniaturization techniques use three-dimensional (3D) integrated circuits (ICs) (3DICs) to achieve higher device packing density, lower interconnect delay, and lower costs. Currently, there are several techniques to manufacture or form 3DICs.

A first technique to form a 3DIC is selective epitaxial layer growth. Selective epitaxial layer growth can produce acceptably decent quality ICs, but this technique is expensive due to the rigorous requirements associated with the process. A second technique to form a 3DIC is a wafer-on-wafer manufacturing technique, whereby electronic components are built on two or more semiconductor wafers separately. The two or more semiconductor wafers are stacked, aligned, bonded, and diced into 3DICs. Through silicon vias (TSVs) are required and provided to effectuate electrical connections between the stacked wafers. Misalignment or TSV defects in any of the stacked wafers can result in an entirely defective integrated circuit due to the interdependence of the IC on the various layers. A third technique to form a 3DIC is a die-on-wafer technique, whereby electronic components are built on two semiconductor wafers. In this technique, one wafer is sliced and the singulated dice are aligned and bonded onto die sites of the second wafer. This die-on-wafer technique can also suffer from alignment issues. A fourth technique to form a 3DIC is a die-on-die technique whereby electronic components are built on multiple dice and then stacked, aligned, and bonded. This approach suffers from the same misalignment problem which may render the final 3DIC unusable.

A fifth technique to form a 3DIC is a monolithic technique, whereby electronic components and their connections are built in layers on a single semiconductor wafer. The layers are assembled through an ion-cutting process. The use of the layers in this fashion eliminates the need for precise alignment and TSVs. In the monolithic approach, a receptor wafer is prepared with integrated components thereon. An oxide layer forms on a top surface of the receptor wafer. A donor wafer is prepared by subjecting the donor wafer to an ion (typically hydrogen) implantation process. The surface of the donor wafer with the ion implantation is then stacked onto the oxide layer of the receptor wafer. The oxide layer of the receptor wafer bonds with the surface of the donor wafer through an annealing process. The donor wafer is then removed, transferring a silicon layer to the receptor wafer. Additional electronic components and interconnects are fabricated over the transfer silicon layer sequentially. The monolithic approach is less expensive than epitaxial growth and eliminates the risk of misalignment, resulting in more functional devices than the techniques that rely on alignment.

While an ion-cutting process can be effective in forming 3DICs, the ion-cutting process may leave excess ions in the transfer layer. These excess ions can interfere with operation of transistors created within the 3DIC by introducing unwanted charges or ionic defects in the channel of the transistor.

### SUMMARY OF THE DISCLOSURE

Embodiments disclosed herein include ion-reduced, ion cut-formed three-dimensional (3D) integrated circuits (IC) (3DICs). Related methods and systems are also disclosed. During an ion-cut process for forming a monolithic 3DIC, extra ions are implanted in the donor wafer to effectuate the ion-cut. Excess, residual implanted ions remain implanted in a top layer of the transfer layer of the 3DIC. However, these residual implanted ions can interfere with operation of electronic components in the 3DIC. In this regard, the 3DIC and methods disclosed herein involve reduction or removal of the residual extra ions before further electronic components are created and layered in a 3DIC. In this manner, the extra charge elements introduced by such unwanted extra ions are reduced or removed providing for better functionality in the completed device.

In this regard, in one exemplary embodiment, a 3DIC is provided. The 3DIC comprises a substrate having a first tier of electronic components thereon. The 3DIC also comprises a donor wafer portion having a second tier of electronic components thereon, wherein the donor wafer portion is substantially free of ions introduced to the donor wafer during an ion cutting procedure and wherein the donor wafer portion is substantially free of surface deformation and without thermal diffusion of the ions. The 3DIC also comprises an oxide bond joining the substrate to the donor wafer portion.

In another exemplary embodiment, a 3DIC is provided. The 3DIC comprises a substrate means for providing a first tier of electronic components thereon. The 3DIC also comprises a donor means for providing a second tier of electronic components thereon, wherein the donor means is substantially free of ions introduced to the donor means during an ion cutting procedure and wherein the donor means is substantially free of surface deformation and without thermal diffusion of the ions. The 3DIC also comprises means for bonding the substrate means to the donor means.

In another exemplary embodiment, a method of forming a semiconductor layer within a 3DIC is provided. The method comprises oxide bonding an ion implanted donor wafer to a receptor wafer. The method also comprises cleaving a first portion of the ion implanted donor wafer leaving a second portion of the ion implanted donor wafer bonded to the receptor wafer, the second portion having a residual ion concentration at an exposed surface. The method also comprises chemical mechanical polishing (CMP) the second portion to reduce ions therefrom. The method also comprises oxidizing the second portion at a temperature below 450° C.

In another exemplary embodiment, a method of forming a semiconductor layer within a 3DIC is provided. The method comprises a step for oxide bonding an ion implanted donor wafer to a receptor wafer. The method also comprises a step for cleaving a first portion of the ion implanted donor wafer leaving a second portion of the ion implanted donor wafer bonded to the receptor wafer, the second portion having a residual ion concentration at an exposed surface. The method also comprises a step for CMP the second portion to reduce ions therefrom. The method also includes a step for oxidizing the second portion at a temperature below 450° C.

### BRIEF DESCRIPTION OF THE FIGURES

FIGS. 1A-1E illustrate exemplary conventional steps in an ion cutting process to assemble a three-dimensional (3D) integrated circuit (IC) (3DIC);

FIG. 2 illustrates a flow chart setting forth an exemplary conventional process for ion cutting;

FIG. 3 is a flow chart of an exemplary process for removing excess, residual ions from a 3DIC;

FIG. 4 illustrates an exemplary ion cutting step in the process of FIG. 3;

FIG. 5 illustrates an exemplary chemical mechanical polish step in the process of FIG. 3;

FIG. 6 illustrates an exemplary oxidation step in the process of FIG. 3;

FIG. 7 illustrates an exemplary etching and cleaning step in the process of FIG. 3;

FIG. 8 illustrates an exemplary second tier formation step in the process of FIG. 3;

FIG. 9 illustrates a clean transistor produced by the exemplary process of FIG. 3; and

FIG. 10 is a block diagram of an exemplary processor-based system that can include the ion-reduced, ion cut-formed 3DIC of the present disclosure.

### DETAILED DESCRIPTION

With reference now to the drawing figures, several exemplary embodiments of the present disclosure are described. The word “exemplary” is used herein to mean “serving as an example, instance, or illustration.” Any embodiment described herein as “exemplary” is not necessarily to be construed as preferred or advantageous over other embodiments.

Embodiments disclosed herein include ion-reduced, ion cut-formed three-dimensional (3D) integrated circuit (IC) (3DICs). Related methods and systems are also disclosed. During an ion-cut process for forming a monolithic 3DIC, extra ions are implanted in the donor wafer to effectuate the ion-cut. Excess, residual implanted ions remain implanted in a top layer of the transfer layer of the 3DIC. However, these residual implanted ions can interfere with operation of electronic components in the 3DIC. In this regard, the 3DIC and methods disclosed herein involve reduction or removal of the residual extra ions before further electronic components are created and layered in a 3DIC. In this manner, the extra charge elements introduced by such extra ions are reduced or removed providing for better functionality in the completed device.

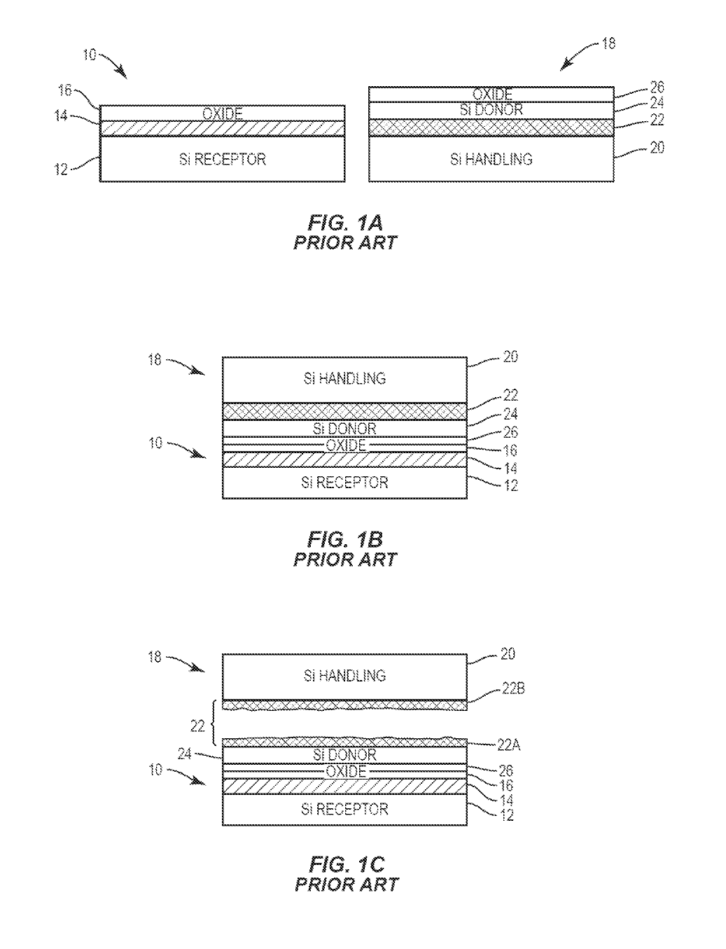

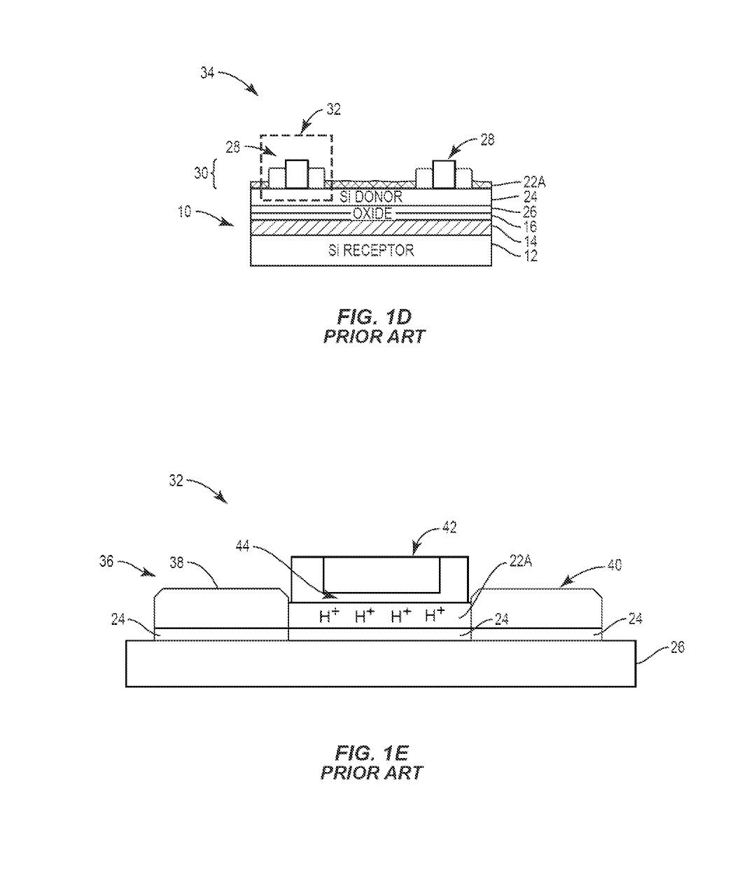

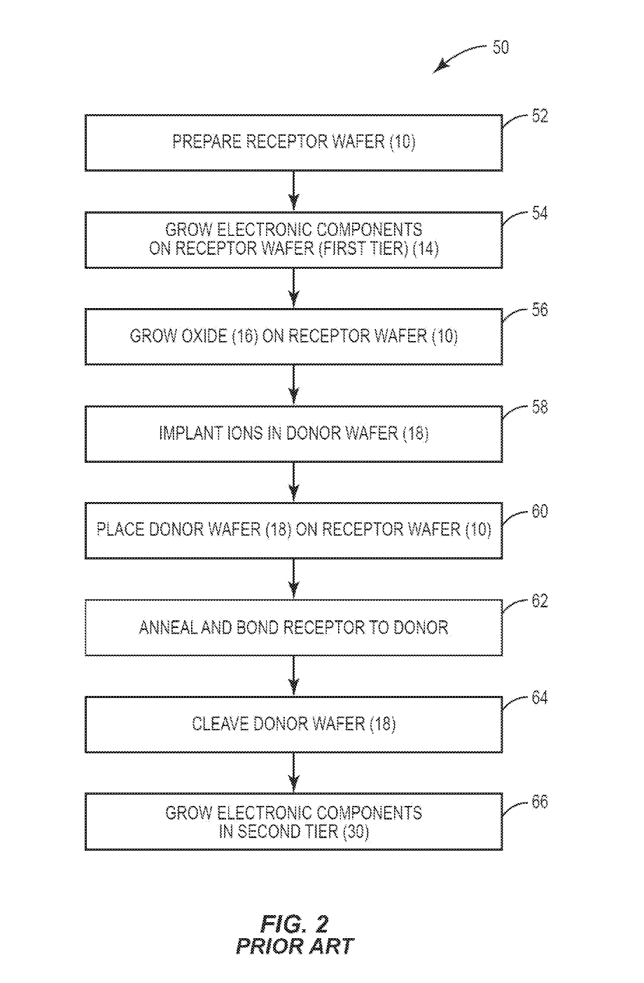

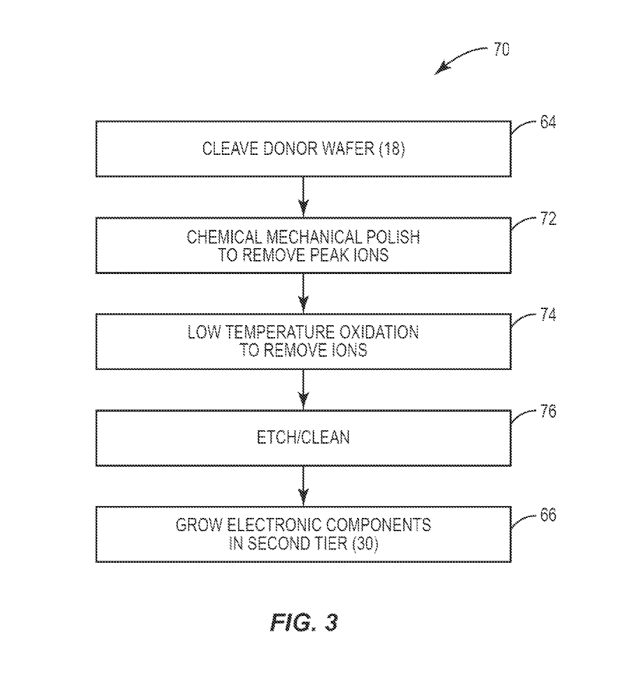

Before discussing embodiments of an ion cutting process that removes or reduces the extra ions during the assembly of a 3DIC, a brief overview of a conventional ion cutting process used in the assembly of a 3DIC is provided with reference to FIGS. 1A-1E and FIG. 2. The discussion of exemplary embodiments of an ion cutting process that removes or reduces the extra ions during the assembly of a 3DIC begins below with reference to FIG. 3.

In this regard, FIG. 1A illustrates a first step of a conventional process to create a 3DIC. Specifically, a receptor wafer 10 is provided having a substrate 12 such as a silicon (Si) substrate. The substrate 12 may be referred to as a substrate means. A first tier of electronic components (generically indicated at 14) are grown on the substrate 12 as is well known. An oxide layer 16 is grown over the electronic components 14. Concurrently a donor wafer 18 is prepared. The donor wafer 18 may be referred to as a donor means. The donor wafer 18 may also be a silicon material. The donor wafer 18 is implanted with ions to form an ionized region 22, which effectively separates a handling portion 20 from a donor portion 24. Conventional implantation processes allow the creation of a localized, high concentration zone (sometimes called a Delta implant zone). In an exemplary process, the ions are hydrogen ions. An oxide layer 26 is grown on the donor portion 24.

With reference to FIG. 1B, the donor wafer 18 is stacked on top of the receptor wafer 10 such that the oxide layer 16 is in contact with the oxide layer 26. The oxide layers 16, 26 may be referred to as a means for bonding. The oxide layers 16, 26 bond and are annealed through a relatively low temperature process (e.g., between approximately 250° C. and 350° C.). Following annealing, the donor wafer 18 is cleaved from the receptor wafer 10 as illustrated in FIG. 1C. The oxide layer 26, the donor portion 24, and a cleaved portion 22A of the ionized region 22 remain attached to the receptor wafer 10 and a residual portion 22B of the ionized region 22 remains on the handling portion 20 of the donor wafer 18 as is well understood.

After cleaving, with reference to FIG. 1D additional electronic components 28, such as transistors are grown on the donor portion 24 to form a second tier of electronic components 30. Additional tiers of electronic components beyond the second tier of electronic components 30 (not illustrated) may be created by repeating the process to create a multi-level or multi-tier 3DIC. A portion 32 of the 3DIC 34 is illustrated in isolation in FIG. 1E, but is also shown within the 3DIC 34 in FIG. 1D to provide context.

With reference to FIG. 1E, the portion 32 of the 3DIC 34 illustrates a transistor 36 having a source 38, a drain 40, and a gate 42. The gate 42 is disposed on the cleaved portion 22A. Residual implanted ions 44, which in an exemplary embodiment are hydrogen ions, remain within the cleaved portion 22A and, in this construction are in the channel portion (i.e., below the gate 42) of the transistor 36. These residual implanted ions 44 are mobile and degrade channel electrostatic control and performance. High temperature techniques to remove the residual implanted ions 44 that are normally used in conventional (SOI) wafer preparation are contra-indicated because such high temperature techniques may damage the first tier of electronic components 14 through thermal diffusion or cause other outgassing related problems. Thermal diffusion may, in effect, widen the cleaved portion 22A as the ions diffuse and spread through the silicon. Because these implanted ions 44 impede operation of the transistor 36, their removal at low temperature is critical for high performance monolithic 3DIC.

With FIGS. 1A-1E providing a visual depiction of an exemplary conventional ion cutting process 50, this conventional ion cutting process 50 is further presented in flow chart form in FIG. 2. The conventional ion cutting process 50 begins with the preparation of the receptor wafer 10 (block 52). Preparation of the receptor wafer 10 involves preparing the substrate 12 and may involve doping, curing, cutting, or other techniques as is well understood. Once prepared, a first tier of electronic components 14 are grown on the receptor wafer 10 (block 54). Once the electronic components 14 are grown, an oxide layer 16 is grown on the receptor wafer 10 (block 56, see also FIG. 1A).

With continued reference to FIG. 2, concurrently or sequentially, ions are implanted in the donor wafer 18 to form the ionized region 22 (block 58, see also FIG. 1A). As noted above, the ions are, in an exemplary embodiment, hydrogen ions. Oxide layer 26 is grown on the donor wafer 18 as well. The donor wafer 18 is placed on the receptor wafer 10 (block 60, see also FIG. 1B). The stack of donor wafer 18 and receptor wafer 10 is annealed (typically at a temperature range of approximately 250 to 350° C.) (block 62), fusing the oxide layers 16, 26. The annealing takes place until cracking of the ionized region 22 takes place, which enables the transfer of a donor portion 24 and cleaved portion 22A from the donor wafer 18 to the receptor wafer 10. This transfer is referred to as cleaving the donor wafer 18 (block 64, see also FIG. 1C). In exemplary methodologies the donor portion 24 is approximately 1.3 μm thick. Following the transfer, a second tier of electronic components 30 may be grown on the donor portion 24 (block 66, see also FIG. 1D). As should be appreciated, some portion of the cleaved portion 22A will be incorporated into or underneath individual ones of the additional electronic components 28.

As noted above, a problem with the conventional approach to building the 3DIC 34 is the presence of residual ions (e.g., residual implanted ions 44) in the cleaved portion 22A. The residual implanted ions 44 interfere with the operation of electronic components and particularly interfere with the second tier of electronic components 30. Embodiments of the present disclosure allow for the reduction or removal of the residual implanted ions 44 through a chemical mechanical polishing (CMP) process followed by an low temperature oxidation step which scours the residual implanted ions 44 from the cleaved portion 22A such that the cleaved portion 22A is substantially free of residual implanted ions. As used herein the terms “reduce” and “remove” are treated equivalently and are intended to reflect a reduction in the presence of ions by at least fifty percent relative to the original implantation. Once the ions are reduced or removed, construction of a 3DIC may continue. Operation of final formed 3DIC is improved in the reduction or absence of the residual implanted ions. While complete removal (e.g., substantially 100%) of the residual implanted ions may result in the most improved operation, reduction such that the cleaved portion 22A is substantially free of ions is likely to return comparable results, and a reduction or removal by the defined 50% provides sufficiently improved operation.

In this regard, FIG. 3 illustrates a flow chart of a process 70 for removing residual implanted ions 44 in a 3DIC according to an exemplary embodiment. The process 70 is initially substantially similar to process 50 up to cleaving the donor wafer 18 (block 64) and those preliminary activities are not repeated in FIG. 3. After cleaving the donor wafer 18 (block 64), the cleaved portion 22A is CMP to remove or otherwise reduce the concentration of peak ions (block 72). In an exemplary embodiment, a ten (10) to twenty (20) nanometer (nm) surface polish is provided. That is, approximately 10-20 nm of the cleaved portion 22A is removed by the polishing action. Such polish physically removes ionized silicon material from the cleaved portion 22A. Since the ionized region 22 is relatively thin before cleaving, and the cleaving splits the ionized region 22, this polishing may remove a large portion of the cleaved portion 22A. A low temperature oxidation may be performed to remove or otherwise reduce further ions (block 74). In an exemplary non-limiting embodiment, the temperature is below 450° C., and the oxidizing agent is ozone (O₃) and/or radical oxygen (O). Ozone and radical oxygen are particularly reactive and react readily with hydrogen ions. Approximately one (1) to two (2) nm oxidation reduces CMP damage and gathers residual implanted ions 44, effectively removing such ions.

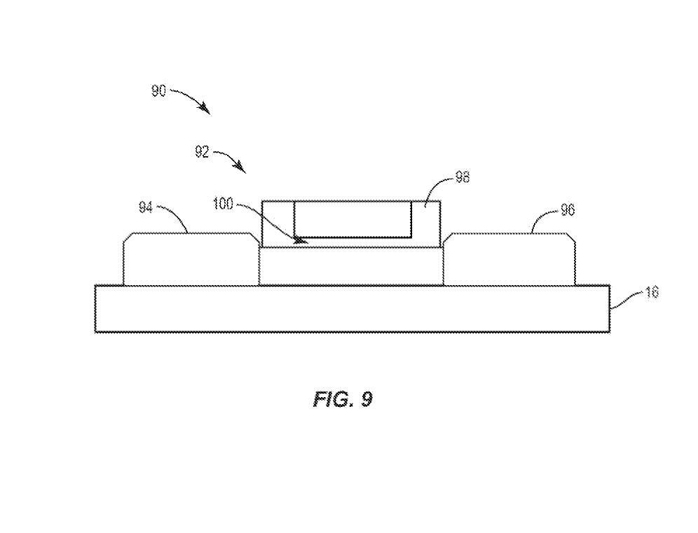

With continued reference to FIG. 3, after an initial oxidation, another oxidation may be performed to etch and, or clean the exposed surface (block 76). After cleaning, the second tier of electronic components 30 may be grown on the exposed surface (block 66). The various stages of the process 70 are illustrated in FIGS. 4-8 and a portion of an exemplary finished 3DIC is illustrated in FIG. 9 to be contrasted with the portion 32 of finished 3DIC 34 of FIGS. 1D and 1E.

In this regard, FIG. 4 illustrates the cleaving of the donor wafer 18. Note that the donor wafer 18 may include not just the ionized region 22, but may also include other types of doping within the donor portion 24 such as p-type doping region 80 and n-type doping region 82. In an exemplary embodiment, the doping of these regions occurs before the ion cutting as well implantation after ion cutting requires a high temperature annealing process. The doping regions 80, 82 may be present to prepare for N/P metal oxide semiconductor field effect transistor (MOSFET) construction. That is, such MOSFETs may be present in the second tier of electronic components 30. After cleaving, the break between the cleaved portion 22A and the residual portion 22B may be a rough surface 84. Note that the vertical dimensions of FIG. 4 have been exaggerated for ease in viewing the respective elements. It should be appreciated that the cleaved portion 22A is substantially thinner than the donor portion 24.

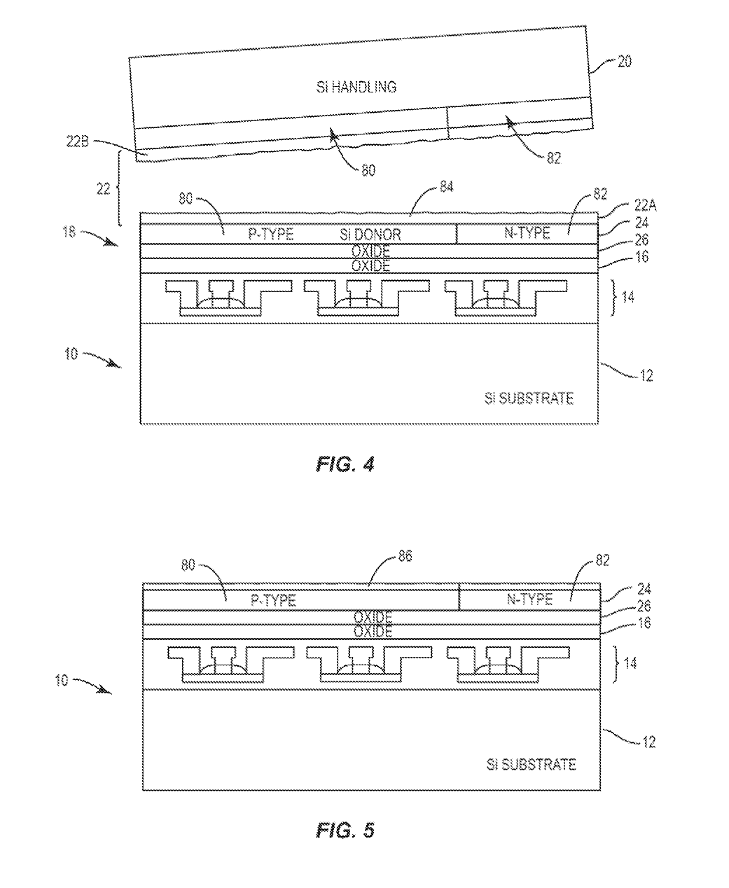

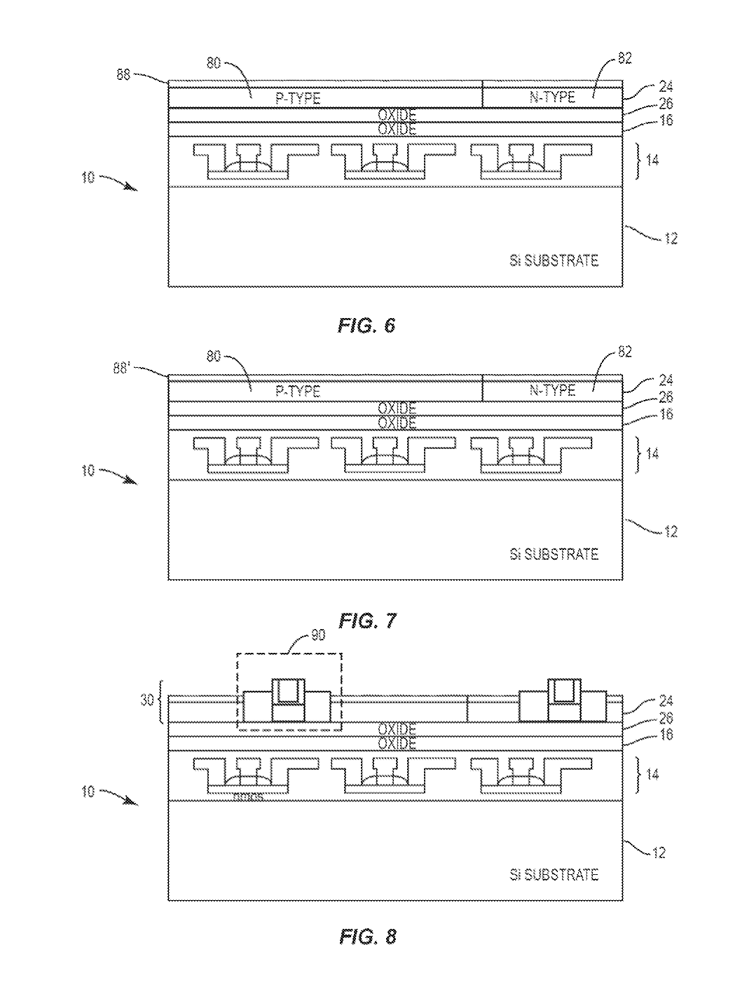

With reference to FIG. 5, a CMP process is then applied to the exposed rough surface 84 of the cleaved portion 22A. This CMP process smoothes the exposed rough surface 84 into exposed surface 86. As noted above, the CMP may affect approximately 10-20 nm of the cleaved portion 22A. However, residual implanted ions 44 (not illustrated in FIG. 5) may still remain in the cleaved portion 22A after the CMP step, so a low temperature oxidation (e.g., less than approximately 450° C. in one embodiment, and less than approximately 400° C. in a second embodiment, and less than approximately 350° C. in a third embodiment) is performed on the exposed surface 86. In an exemplary embodiment the oxidizing agent is ozone or radical oxygen and approximately one (1) to two (2) nm is oxidized into a surface oxidized layer 88, as seen in FIG. 6. This oxidation reduces CMP damage and scours most or substantially all of the remaining residual implanted ions 44 such that the cleaved portion 22A is substantially free of residual implanted ions 44 (e.g. hydrogen ions) that were introduced during the ion cutting procedure.

With reference to FIG. 7, a second oxidation step may be performed to etch and/or clean the surface oxidized layer 88′. After cleaning, the second tier of electronic components 30 are grown on the surface oxidized layer 88′ as illustrated in FIG. 8. The electronic components in the second tier of electronic components 30 may be nmos or pmos for a region of a given doping type (e.g., doping regions 80, 82). In an exemplary embodiment, an inversion channel nmos or a junctionless pmos transistor may be formed in p-type doping region 80. Similarly, an inversion channel pmos or a junctionless nmos transistor may be formed in n-type doping region 82. An isolated electronic component 90 is extracted and illustrated in FIG. 9. The isolated electronic component 90 is a transistor 92 and includes a source 94, a drain 96, and gate 98. Unlike the isolated portion 32 of FIG. 1E, the channel 100 of the transistor 92 is substantially free of residual implanted ions 44 and operation of the transistor 92 is not degraded.

The 3DIC according to embodiments disclosed herein may be provided in or integrated into any processor-based device. Examples, without limitation, include a set top box, an entertainment unit, a navigation device, a communications device, a fixed location data unit, a mobile location data unit, a mobile phone, a cellular phone, a computer, a portable computer, a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, and a portable digital video player.

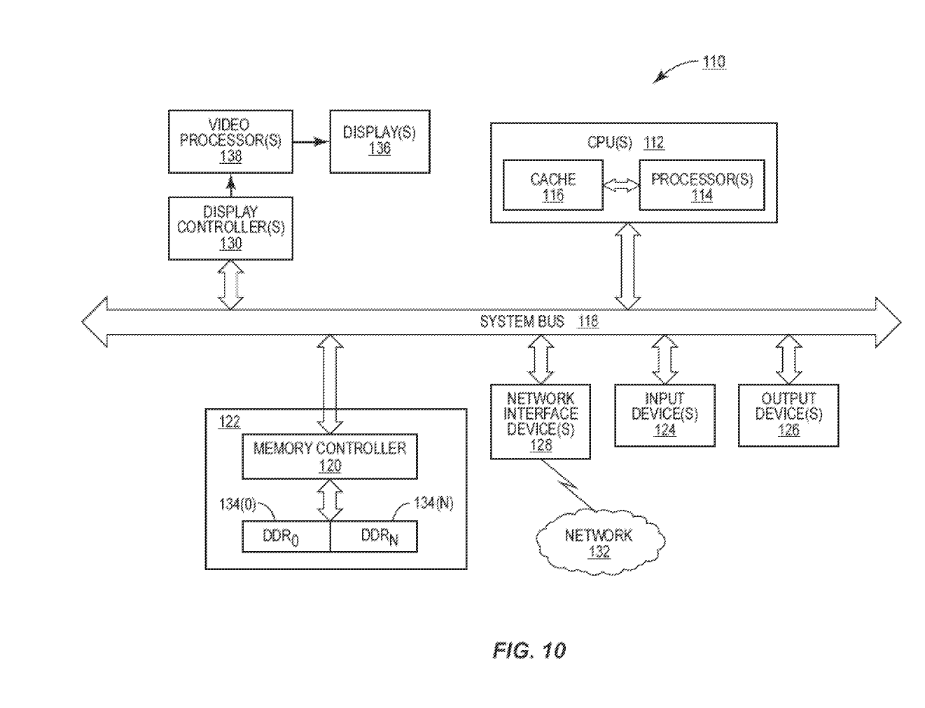

In this regard, FIG. 10 illustrates an example of a processor-based system 110 that can employ a 3DIC. In this example, the processor-based system 110 includes one or more central processing units (CPUs) 112, each including one or more processors 114. The CPU(s) 112 may have cache memory 116 coupled to the processor(s) 114 for rapid access to temporarily stored data. The CPU(s) 112 is coupled to a system bus 118 and can intercouple master devices and slave devices included in the processor-based system 110. As is well known, the CPU(s) 112 communicates with these other devices by exchanging address, control, and data information over the system bus 118. For example, the CPU(s) 112 can communicate bus transaction requests to the memory controller 120. Although not illustrated in FIG. 10, multiple system buses 118 could be provided, wherein each system bus 118 constitutes a different fabric.

Other devices can be connected to the system bus 118. As illustrated in FIG. 10, these devices can include a memory system 122, one or more input devices 124, one or more output devices 126, one or more network interface devices 128, and one or more display controllers 130, as examples. The input device(s) 124 can include any type of input device, including but not limited to input keys, switches, voice processors, etc. The output device(s) 126 can include any type of output device, including but not limited to audio, video, other visual indicators, etc. The network interface device(s) 128 can be any devices configured to allow exchange of data to and from a network 132. The network 132 can be any type of network, including but not limited to a wired or wireless network, private or public network, a local area network (LAN), a wide local area network (WLAN), and the Internet. The network interface device(s) 128 can be configured to support any type of communication protocol desired. The memory system 122 can include one or more memory units 134(0-N).

The CPU(s) 112 may also be configured to access the display controller(s) 130 over the system bus 118 to control information sent to one or more displays 136. The display controller(s) 130 sends information to the display(s) 136 to be displayed via one or more video processors 138, which process the information to be displayed into a format suitable for the display(s) 136. The display(s) 136 can include any type of display, including but not limited to a cathode ray tube (CRT), a liquid crystal display (LCD), a plasma display, etc.

Those of skill in the art will further appreciate that the various illustrative logical blocks, modules, circuits, and algorithms described in connection with the embodiments disclosed herein may be implemented as electronic hardware, instructions stored in memory or in another computer-readable medium and executed by a processor or other processing device, or combinations of both. The arbiters, master devices, and slave devices described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the embodiments disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices. e.g., a combination of a DSP and a microprocessor, a plurality of microprocessors, one or more microprocessors in conjunction with a DSP core, or any other such configuration.

The embodiments disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary embodiments herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary embodiments may be combined. It is to be understood that the operational steps illustrated in the flow chart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

1. A three-dimensional (3D) integrated circuit (IC) (3DIC) comprising:
a substrate having a first tier of electronic components thereon;
a donor wafer portion having a second tier of electronic components thereon, wherein the donor wafer portion is substantially free of ions introduced to the donor wafer portion during an ion cutting procedure and wherein the donor wafer portion is substantially free of surface deformation and without thermal diffusion of the ions; and
an oxide bond joining the substrate to the donor wafer portion.

2. The 3DIC of claim 1 wherein the substrate comprises a silicon substrate.

3. The 3DIC of claim 1, wherein the donor wafer portion is substantially free of hydrogen ions introduced during the ion cutting procedure.

4. The 3DIC of claim 1, wherein the donor wafer portion includes a p-type doping portion.

5. The 3DIC of claim 1, wherein the donor wafer portion includes an n-type doping portion.

6. The 3DIC of claim 1, integrated into a semiconductor die.

7. The 3DIC of claim 1, further comprising a device selected from the group consisting of: a set top box, an entertainment unit, a navigation device, a communications device, a fixed location data unit, a mobile location data unit, a mobile phone, a cellular phone, a computer, a portable computer, a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, and a portable digital video player, into which the 3DIC is integrated.

8. A three-dimensional (3D) integrated circuit (IC) (3DIC) comprising:
a substrate means for providing a first tier of electronic components thereon;
a donor means for providing a second tier of electronic components thereon, wherein the donor means is substantially free of ions introduced to the donor means during an ion cutting procedure and wherein the donor means is substantially free of surface deformation and without thermal diffusion of the ions; and
means for bonding the substrate means to the donor means.

9. The 3DIC of claim 8, wherein the donor means is substantially free of hydrogen ions introduced during the ion cutting procedure.

10. The 3DIC of claim 8, wherein the donor means includes a p-type doping portion.

11. The 3DIC of claim 8, wherein the donor means includes an n-type doping portion.

12. A method of forming a semiconductor layer within a three-dimensional (3D) integrated circuit (IC) (3DIC), the method comprising:
oxide bonding an ion implanted donor wafer to a receptor wafer;
cleaving a first portion of the ion implanted donor wafer leaving a second portion of the ion implanted donor wafer bonded to the receptor wafer, the second portion having a residual ion concentration at an exposed surface;
chemical mechanical polishing (CMP) the second portion to reduce ions therefrom; and
oxidizing the second portion at a temperature below 450° C.

13. The method of claim 12, further comprising implanting ions in the donor wafer.

14. The method of claim 13, wherein implanting ions in the donor wafer comprises implanting hydrogen ions in the donor wafer.

15. The method of claim 12, wherein the oxidizing occurs after the CMP to reduce mechanical damage.

16. The method of claim 15, wherein reactive oxidizing further removes ions from the second portion.

17. The method of claim 15, wherein oxidizing comprises using one or more of ozone and radical oxygen to oxidize.

18. The method of claim 12, further comprising forming circuit components in the receptor wafer as a first tier of the 3DIC prior to the oxide bonding.

19. The method of claim 18, further comprising forming additional circuit components on an exposed surface of the donor wafer to form a second tier of the 3DIC after CMP.

20. A method of forming a semiconductor layer within a three-dimensional (3D) integrated circuit (IC) (3DIC), the method comprising:
a step for oxide bonding an ion implanted donor wafer to a receptor wafer;
a step for cleaving a first portion of the ion implanted donor wafer leaving a second portion of the ion implanted donor wafer bonded to the receptor wafer, the second portion having a residual ion concentration at an exposed surface;
a step for chemical mechanical polishing (CMP) the second portion to reduce ions therefrom; and
a step for oxidizing the second portion at a temperature below 450° C.
